(19) United States
(12) Patent Application Publication
(10) Pub. No.: US 2006/0138501 A1
(43) Pub. Date: Jun. 29, 2006

(54) Semi-conductor dielectric component with a praseodymium oxide dielectric

(76) Inventors: Hans-Joachim Mussig, Dresden (DE); Dieter Schmeisser, Cottbus (DE)

Correspondence Address: WARE FRESSOLA VAN DER SLUYS &;ADOLPHSON, LLP, BRADFORD GREEN BUILDING 5, 755 MAIN STREET, P O BOX 224, MONROE, CT, 06468, US

(21) Appl. No.: 10/528,868

(22) PCT Filed: Sep. 24, 2003
(86) PCT No.: PCT/EP03/10625

§ 371 Date: Oct. 13, 2005

(30) Foreign Application Priority Data
Sep. 26, 2002 (DE) 102 45 590.2

(51) Int. Cl. H01L 29/94

(52) U.S. Cl. 257/295

(57) ABSTRACT

A semiconductor component having a silicon-bearing layer and a praseodymium oxide layer, wherein arranged between the silicon-bearing layer and the praseodymium oxide layer is a mixed oxide layer containing silicon, praseodymium and oxygen. The layer is of a thickness of a maximum of 5 nanometers. A production process for such a semiconductor component is also provided. It is possible by means of the mixed oxide layer to improve on the one hand the capacitance of the component in relation to previously known components which contain a silicon oxide intermediate layer. On the other hand a high level of charge carrier mobility is achieved without the necessity for a silicon oxide intermediate layer.

### CROSS REFERENCE TO RELATED APPLICATIONS

This application is for entry into the U.S. national phase under §371 for International Application No. PCT/EP03/10625 having an international filing date of Sep. 24, 2003, and from which priority is claimed under all applicable sections of Title 35 of the United States Code including, but not limited to, Sections 120, 363 and 365(c), and which in turn claims priority under 35 USC §119 to German Patent Application No. 102 45 590.2-33 filed on Sep. 26, 2002.

### TECHNICAL FIELD

The invention concerns a semiconductor component with a silicon-bearing layer and a praseodymium oxide layer. The invention further concerns a process for the production of such an electronic component.

### BACKGROUND ART

Pr₂O₃ layers on Si(001) substrates, because of their comparatively high dielectric constant (k≈30), are particularly suitable for replacing the traditional gate-dielectric material SiO₂ in sub-0.1 μm CMOS technology. It is however generally assumed that an ultra-thin SiO₂ layer is necessary between the Si substrate and an alternative dielectric material in order to match bondings and charges to each other and to reduce mechanical stresses and in that way to achieve a high level of charge carrier mobility.

As the following consideration shows, such a thin SiO₂ intermediate layer reduces the dielectric effectiveness of the substitute material. If we assume that the thickness t_{high.k} of the alternative dielectric is to afford the same capacitance as an SiO₂ layer of the equivalent thickness t_{eq}, that gives:
thigh−k=(khigh−k/kSiO2)teq, (1)
wherein k_{SiO2} is the dielectric constant of the SiO₂. As the SiO₂ intermediate layer represents a second capacitance C_{SiO2} connected in series with the alternative dielectric, the resulting capacitance can be calculated as follow:
1/Cᵣₑₛ=1/C_{high-k}+1/C_{SiO2}, (2)
wherein C_{high-k} is the capacitance of the dielectric layer. Using (1), that then gives the following for the equivalent thickness of the layer system t^{s}_{eq}, comprising a thin SiO₂ layer t_{SiO2} and the dielectric layer t_{high-k},
t^{s}_{eq}=t_{SiO2}+(k_{SiO2}/k_{high-k})t_{high-k}, (3)

It follows directly from (3) that the minimum attainable equivalent oxide thickness t^{s}_{eq} can never be less than the thickness t_{SiO2} of the SiO₂ layer. This therefore jeopardizes the increase in capacitance which is sought to be achieved with the use of a material with a high dielectric constant.

While a very high capacitance in respect of the layer, in the case of extremely slight leakage currents, is essential for use of the material in dynamic RAMs (DRAMs), a very high interface quality and charge carrier mobility in the channel are crucial for use of the material in MOSFETs.

### DISCLOSURE OF THE INVENTION

The technical object of the present invention is to provide a semiconductor component of the kind set forth in the opening part of this specification, with a sufficiently high capacitance and charge carrier mobility, even with particularly small dimensions. A further object of the invention is to provide a process for the production of such a component.

In regard to the semiconductor component that object is attained by a semiconductor component having a silicon-bearing layer and a praseodymium oxide layer, wherein arranged between the silicon layer and the praseodymium oxide layer is a mixed oxide layer containing silicon, praseodymium and oxygen, which is of a layer thickness of less than 5 nanometers.

The invention is based on the realization that a mixed oxide containing silicon, praseodymium and oxygen is suitable for combining the advantageous properties of the hitherto usual SiO₂/Si(001) interface with those of the alternative dielectric praseodymium oxide (for example in the form of Pr₂O₃).

The mixed oxide which hereinafter is also referred to praseodymium silicate has a greater dielectric constant in comparison with silicon oxide. On the assumption that the mixed oxide layer is of the same thickness as an otherwise necessary silicon oxide intermediate layer between the silicon-bearing substrate and the praseodymium oxide, the minimum attainable equivalent oxide is reduced, in accordance with equation (3), by a factor which corresponds to the ratio of the dielectric constants of praseodymium silicate and silicon oxide.

The mixed oxide layer affords a high level of charge carrier mobility in the component according to the invention in accordance with the present state of knowledge by virtue of the fact that there are Si—O bonds and no Si—Pr bonds at the interface relative to the silicon-bearing layer. The Si—O bonds afford electrical properties as are known from the SiO₂/Si(001) interface.

Accordingly by means of the mixed oxide layer according to the invention it is possible to guarantee on the one hand a very high level of interface quality and on the other hand a sufficiently high capacitance. A transition from the silicon-bearing substrate to the dielectric is achieved, which has all the required properties.

In accordance with the foregoing, the thickness of the mixed oxide layer influences the capacitance of a capacitor structure which includes the silicon-bearing layer and the praseodymium oxide layer in a semiconductor component according to the invention. According to the invention the layer thickness is at a maximum 5 nm. The higher the value of the capacitance that is sought to be achieved for a component according to the invention, the correspondingly smaller should be the selected layer thickness of the mixed oxide layer.

Therefore in most cases small mixed oxide layer thicknesses are preferred. In an embodiment of the invention the mixed oxide layer involves a layer thickness of a maximum of 3 nm.

In an embodiment of the invention which is particularly preferred at the present time the mixed oxide layer is a pseudo-binary, non-stoichiometric alloy of the type (Pr₂0₃)ₓ(SiO₂)₁₋ₓ or a silicate of that type.

The value of x has been found to be dependent inter alia on the layer thickness. In other words, in the case of components involving different thicknesses for the mixed oxide layer, the coeffients x differ. The coefficient x increases with the layer thickness. A detailed analysis of the composition of the mixed oxide, characterized by x, has revealed that the value x increases from 0.3 to 1 with thickness, in the layer thickness range up to 3 nm.

In a further embodiment of the invention the coefficient x increases between the silicon-bearing layer and the praseodymium oxide layer. In this embodiment the coefficient x increases within the mixed oxide layer.

In a preferred embodiment the silicon-bearing layer comprises doped or undoped silicon. It is however also possible to provide a doped or undoped silicon-germanium alloy in the silicon-bearing layer. When silicon-germanium alloy is used, nitrogen can additionally be incorporated into the silicon-bearing layer to achieve a high-quality interface.

In that case the silicon-bearing layer at the interface to the mixed oxide layer preferably involves a (001) orientation. A particularly high level of interface quality is achieved in that way.

The component according to the invention can preferably be in particular in the form of an MOSFET (metal oxide semiconductor field effect transistor) or in the form of a memory component in a RAM unit (random access memory) like a dynamic ROM (DROM).

In regard to the process aspect the object of the invention is attained by a production process for an electronic component with a step of depositing a praseodymium oxide layer on a silicon-bearing layer, wherein prior to said deposit step a step of depositing a mixed oxide layer containing silicon, praseodymium and oxygen is effected at a substrate temperature of less than 700° C.

The process according to the invention is based on the realization that the underlying object thereof is to be attained if it is possible for the alternative dielectric material praseodymium oxide Pr₂O₃ to be so grown on Si(001) that no SiO₂ intermediate layer occurs and also such a layer is not necessary to achieve a sufficiently high level of charge carrier mobility.

That is achieved by a mixed oxide layer being grown on the silicon-bearing layer. That mixed oxide layer contains silicon, praseodymium and oxygen.

It is of great significance in terms of the interface quality and thus the charge carrier mobility that no silicides are formed in the semiconductor component according to the invention at the interface to the substrate. Here use is inventively made of the fact that, in the temperature range up to 800° C., praseodymium ions are subjected to repulsion forces at the surface of the silicon-bearing substrate material so that Si—O bonds and not Si—Pr bonds occur there. In other words, no silicides are formed at the interface to the substrate. The Si—O bonds which are produced instead at the interface afford particularly good electrical properties as are known from the SiO₂/Si(001) interface.

Accordingly, a chemically reactive interface exists, comprising an Si—Pr mixed oxide of the form (Pr₂O₃)ₓ(SiO₂)₁₋ₓ, which is typically of a non-stoichiometric composition.

The upper temperature limit of 700° C. which is predetermined in accordance with the invention prevents decomposition of structure elements of the component produced, in particular the mixed oxide layer itself.

Preferably the steps of depositing a mixed oxide layer and depositing a praseodymium oxide layer are effected in the form of deposition out of the gaseous phase. Particularly controlled growth of the layers is achieved in that way.

The above-mentioned deposit steps can be effected by means of molecular beam deposition (molecular beam epitaxy or MBE) or by means of chemical vapor deposition or CVD.

In a particularly preferred embodiment of the process according to the invention the step of depositing the mixed oxide layer is effected in an oxygen-bearing gas atmosphere. As will be described in greater detail hereinafter with reference to FIG. 1, it has been found that the presence of oxygen in the gas atmosphere of the growth chamber is of great significance in regard to controlling the layer composition. Thus particularly when there is a lack of oxygen, silicon monoxide SiO is produced instead of silicon dioxide SiO₂. The provision of oxygen makes it possible to control the composition, that is to say the stoichiometry coefficient x of the silicate (Pr₂0₃)ₓ(SiO₂)₁₋ₓ. A provision of oxygen is of great importance for the production of the Si—O bonds in the region of the interface by virtue of the high reactivity of silicon from the silicon-bearing layer and oxygen.

An oxygen-bearing gas atmosphere is also advantageous for deposit of the praseodymium oxide layer.

Preferably a material which contains praseodymium oxide in the form of Pr₆O₁₁ or which even completely consist thereof is used as a starting material for the step of depositing the mixed oxide layer. The reduction of praseodymium oxide Pr₆O₁₁ in the growth chamber provides for an oxygen partial pressure with which the layer growth takes place in the desired manner. In this embodiment the oxygen content of the gas atmosphere can be controlled by means of the temperature.

Preferably the step of depositing the mixed oxide layer is effected at a substrate temperature of less than 680° C., in particular between 600° C. and 650° C. Particularly when using Pr₆O₁₁ as starting material, it is possible in that temperature range to guarantee sufficient provision of oxygen which leads to the formation of the mixed oxide (Pr₂0₃)ₓ(SiO₂)₁₋ₓ.

### BRIEF DESCRIPTION OF THE DRAWINGS

The invention is described in greater detail hereinafter with reference to two Figures of drawings in which:

FIG. 1 shows a ternary phase diagram for the praseodymium-oxygen-silicon system, and

FIG. 2 shows an embodiment of the semiconductor component according to the invention.

### DETAILED DESCRIPTION OF THE INVENTION

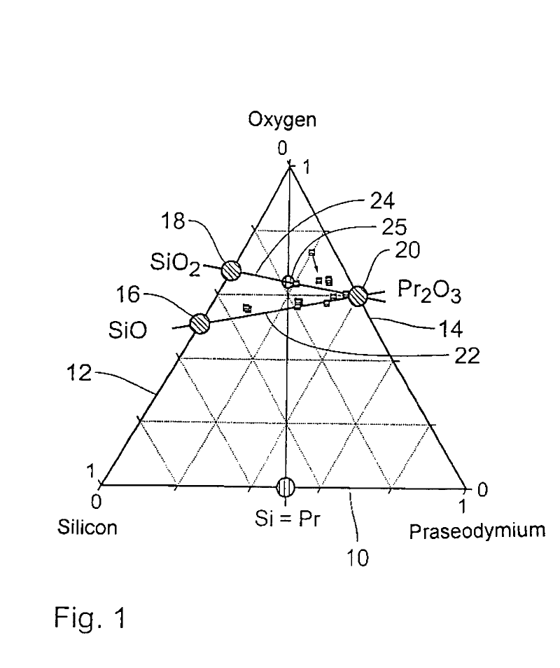

FIG. 1 shows a ternary phase diagram for the praseodymium-oxygen-silicon system. That phase diagram was experimentally ascertained in the context of research work in connection with the present invention.

The phase diagram has three co-ordinate axes 10, 12 and 14 arranged in the form of an equilateral triangle. The elements praseodymium, oxygen and silicon are associated with the corner points of the equilateral triangle. The concentration of those elements corresponds there to the value 1. The concentration of the respective element falls along the sides of the triangle, to the value zero.

Silicon monoxide SiO is present with a silicon content 0.5. That point of the phase diagram is identified by reference numeral 16. Silicon dioxide SiO₂ is present with a silicon content of 0.33. That point of the phase diagram is identified by reference numeral 18. Along the co-ordinate axis 14 the phase contains exclusively praseodymium and oxygen and no silicon. The Figure also shows the point 20 at which praseodymium oxide is present in the form Pr₂O₃.

Various experimentally ascertained phases of the mixed oxide are illustrated within the triangle formed by the three co-ordinate axes 10, 12 and 14, in the form of squares. The experimental values were ascertained by means of photoelectron spectroscopy on the basis of samples grown in the temperature range of between 600 and 650° C. To ascertain their composition the samples were excited with synchrotron radiation and the energy of the electrons emanating from the sample is recorded and analyzed. It is found that the samples ascertained, depending on the respective oxygen content involved, are on a quasi-binary section line 22 representing a mixed phase of praseodymium oxide Pr₂O₃ and silicon monoxide SiO, or on a quasi-binary straight section line 24 representing a mixed phase of praseodymium oxide Pr₂O₃ and silicon dioxide SiO₂. At a point 25 at which the section line 24 intersects the median perpendicular, leading from the apex to the base, of the triangular phase diagram a (Pr₂0₃)ₓ(SiO₂)₁₋ₓ thortveitite structure was ascertained. At that point 25 of the phase diagram the proportion of silicon and praseodymium in the mixed oxide are equal.

The phase diagram in FIG. 1 accordingly shows that it has been possible to produce a praseodymium silicate or a pseudo-binary, non-stoichiometric alloy (Pr₂0₃)ₓ(SiO₂)₁₋ₓ with an adjustable proportion x of the praseodymium oxide Pr₂O₃.

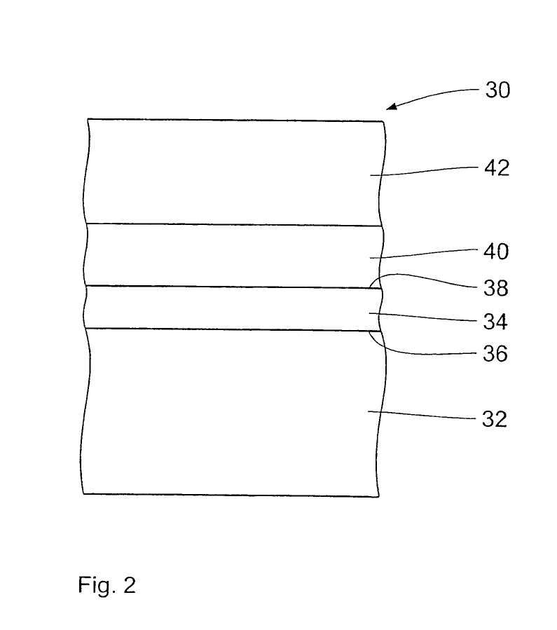

FIG. 2 shows a section of an embodiment of a semiconductor component 30 according to the invention with a silicon substrate 32 and a mixed oxide layer 34 adjoining same. At an interface 36 between the silicon substrate 32 and the mixed oxide layer 34 the substrate has a (001) surface. The mixed oxide layer is a (Pr₂0₃)ₓ(SiO₂)₁₋ₓ layer wherein the coefficient x at the interface 36 is of a value 0.3 and at an interface 38 to an adjacent praseodymium oxide layer (Pr₂O₃) 40 it is of a value 1. A polysilicon layer 42 is arranged above the praseodymium oxide layer 40.

The substrate 32 is not shown in greater detail here in its internal structure. The component 30 which is here also shown only in respect of a section thereof can be for example an MOSFET or a memory element of a DROM memory.

1. A semiconductor component (30) having a silicon-bearing layer (32) and a praseodymium oxide layer (40), characterized in that arranged between the silicon-bearing layer (32) and the praseodymium oxide layer (40) is a mixed oxide layer (34) containing silicon, praseodymium and oxygen, which is of a layer thickness of less than 5 nanometers.

2. A semiconductor component as set forth in claim 1 wherein the mixed oxide layer (34) is of a layer thickness of a maximum of 3 nanometers.

3. A semiconductor component as set forth in claim 1 wherein the mixed oxide (34) is a pseudo-binary, non-stoichiometric silicate or an alloy of the type (Pr₂O₃)ₓ(SiO₂)₁₋ₓ.

4. A semiconductor component as set forth in claim 3 wherein x increases between the silicon-bearing layer (32) and the praseodymium oxide layer (40).

5. A semiconductor component as set forth in claim 1 wherein the silicon-bearing layer (32) comprises doped or undoped silicon-germanium.

6. A semiconductor component as set forth in claim 1 wherein the silicon-bearing layer comprises doped or undoped silicon.

7. A semiconductor component 30 as set forth in claim 5 wherein the silicon-germanium layer or the silicon layer has an (001) orientation at the interface to the mixed oxide layer.

8. An MOSFET as set forth in claim 1.

9. A memory cell as set forth in claim 1.

10. A production process for an electronic component with a step of depositing a praseodymium oxide layer (40) on a silicon-bearing layer (32),
characterized in that prior to said deposit step a step of depositing a mixed oxide layer (34) containing silicon, praseodymium and oxygen is effected at a substrate temperature of less than 700° C.

11. A process as set forth in claim 10 wherein the steps of depositing a mixed oxide layer (34) and depositing a praseodymium oxide layer (40) are effected in the form of deposition out of the gaseous phase.

12. A process as set forth in claim 11 wherein the deposit steps are effected by means of molecular beam deposition.

13. A process as set forth in claim 11 wherein the deposit steps are effected by means of chemical vapor phase deposition.

14. A process as set forth in claim 10 wherein the step of depositing the mixed oxide layer (34) is effected in an oxygen-bearing gas atmosphere.

15. A process as set forth in claim 10 wherein the step of depositing the praseodymium oxide layer (40) is effected in an oxygen-bearing gas atmosphere.

16. A process as set forth in claim 10 wherein the step of depositing the mixed oxide layer (34) is effected by means of a starting material which contains or consists of praseodymium oxide in the form Pr₆O₁₁.

17. A process as set forth in claim 10 wherein the step of depositing the praseodymium oxide layer (40) is effected by means of a starting material containing praseodymium oxide in the form Pr₆O₁₁.

18. A process as set forth in claim 10 wherein the step of depositing the mixed oxide layer (34) is effected at a temperature of a maximum of 680° C.

19. A process as set forth in claim 12 wherein the step of depositing the mixed oxide layer (34) is effected at a temperature of between 600° C. and 650° C.
